(19) United States
(12) Patent Application Publication
(10) Pub. No.: US 2010/0301384 A1
(43) Pub. Date: Dec. 2, 2010

(54) DIODE

(75) Inventors: Iulian NISTOR, Birmenstorf (CH); Arnost Kopta, Zurich (CH); Tobias Wikstroem, Egliswil (CH)

Correspondence Address: BUCHANAN, INGERSOLL & ROONEY PC, POST OFFICE BOX 1404, ALEXANDRIA, VA, 22313-1404, US

(73) Assignee: ABB TECHNOLOGY AG, Zurich (CH)

(21) Appl. No.: 12/819,839

(22) Filed: Jun. 21, 2010

Related U.S. Application Data
(63) Continuation of application No. PCT/EP2008/068043, filed on Dec. 19, 2008.

(30) Foreign Application Priority Data
Dec. 19, 2007 (EP) 07/150156.3
May 14, 2008 (EP) 08156147.4

(51) Int. Cl. H01L 27/06; H01L 29/87; H01L 21/329

(52) U.S. Cl. 257/109; 438/133; 257/140; 257/E21.352; 257/E29.337; 257/E27.019

(57) ABSTRACT

A diode for fast switching applications includes a base layer of a first conductivity type with a first main side and a second main side opposite the first main side, an anode layer of a second conductivity type, which is arranged on the second main side, a plurality of first zones of the first conductivity type with a higher doping concentration than the base layer, and a plurality of second zones of the second conductivity type. The first and second zones are arranged alternately on the first main side. A cathode electrode is arranged on top of the first and second zones on the side of the zones which lies opposite the base layer, and a anode electrode is arranged on top of the anode layer on the side of the anode layer which lies opposite the base layer. The base layer includes a first sublayer, which is formed by the second main sided part of the base layer, and a second sublayer, which is formed by the first main sided part of the base layer. A third layer of the first conductivity type is arranged between the first and second sublayers. The third layer has a higher doping concentration than the base layer and a lower doping concentration than the first zones.

### RELATED APPLICATIONS

This application claims priority as a continuation application under 35 U.S.C. §120 to PCT/EP2008/068043, which was filed as an International Application on Dec. 19, 2008 designating the U.S., and which claims priority to European Application 0750156.3 filed in Europe on Dec. 19, 2007 and European Application 08156147.4 filed in Europe on May 14, 2008. The entire contents of these applications are hereby incorporated by reference in their entireties.

### FIELD

The present disclosure relates to the field of power electronics, and more particularly, to a diode and to a method for manufacturing such a diode.

### BACKGROUND INFORMATION

A conventional diode includes a first n-doped base layer with a first main side and a second main side opposite the first main side. On the second main side, a second p-doped anode layer is arranged, and on top of the p-doped layer, a metal layer which functions as an anode is arranged. On the first main side, a higher (n+) doped buffer layer is arranged. A first metal layer in form of a cathode electrode is arranged on top of the buffer layer. FIGS. 4 and 5 show a snappy turn-off effect of such a conventional diode. FIG. 4 shows the over voltages which arise during the turn-off, and FIG. 5 shows the over currents. Such over voltages and current/voltage oscillations are to be avoided in the normal operation of a power electronic system, as they can lead to damage and destruction of the diode.

An improvement to the before-mentioned diode is described in DE 36 31 136 A1. In this patent application, a fast switching rectifier diode is shown for use at high currents. The diode include a first n-doped base layer 2 with a first main side 21, and a second main side 22 opposite the first main side 21. On the second main side 22, a second p-doped anode layer 3 is arranged and on top of the p-doped anode layer 3, and a metal layer (anode electrode) which functions as an anode is arranged. On the first main side 21, a higher (n+) doped buffer layer 81 is arranged. On that side of the buffer layer 81, which is opposite the base layer, a plurality of first (n++) doped zones 4 with a higher doping concentration than the base layer 2 and a plurality of second (p+) doped zones 5 are arranged alternately. The area of all p+ zones is 5% of the complete area. The doping concentration of the buffer layer 81 is such that the space charge region at full blocking voltage extends close to the (p+) doped second zones 5.

The first and second zones 4, 5 are in contact with each other by a first metal layer 6 in form of a cathode. The metal layer 6 is arranged on top of the first and second zones 4, 5, i.e. on the side opposite the buffer layer 81. On top of the anode layer 3, a second metal layer (anode electrode) 7 is arranged, which has the function of an anode.

FIGS. 6 and 7 show voltage and current during the turn-off for a voltage of 6 kV for a conventional rectifier diode as described in DE 36 31 136 A1, which includes a plurality of second (p+) doped zones 5 as described above (shown by the circle symbols in both figures). The diode does not show over voltages or over currents as shown in FIGS. 4 and 5 for a diode without such second (p+) doped zones.

A disadvantage of the diode like the one described in DE 36 31 136 A1, however, is that during the turn-off process, the space charge region extends close to the p+ doped areas. In this way, the lateral flow of electrons from the body of the diode towards the cathode on the surface of the p+ areas is constricted to a very narrow channel. The resistivity of the channel increases as the space charge region continues to expand towards the cathode, and the lateral voltage drop increases accordingly. The second (p+) doped zones start to inject holes when the reverse recovery current reaches a maximum value. Depending on the current, this process can lead to early destruction of the diode. FIG. 3 shows a comparison between a normal turn off process in snap-off conditions (high voltage, low currents, high di/dt, large stray inductance; measuring results with the rhombus symbol in FIG. 3), and a second turn-off process in similar conditions but at a higher current (measuring results with the square symbol in FIG. 3). The diode design used for these measurements (FIG. 3) is of the conventional diode according to DE 36 31 136, which is schematically shown in FIG. 1. In the second case, i.e. for high currents, due to the strong injection of holes through the mechanism detailed above, the current will fail to return to zero and the diode will be destroyed through overheating.

In all circuit topologies associated with power electronic switches such as for IGCTs (Integrated gate commutated thyristor) or IGBTs (insulated gate bipolar transistor), the diode plays a critical role as a free wheeling device. FIG. 2 shows a simplified circuit including an IGCT 12 switch and clamp circuit. The free wheeling diode 11 is used to create a path for the load current when the IGCT 12 is turned off. When the IGCT 12 is turned on, the diode will become reverse biased, and will undergo a process called “reverse recovery”. The turn-on capability of these switching devices is restricted by the free wheeling diode. Therefore, an improved diode with both high voltage and high recovery performance is desired in high power applications.

During the recovery process, the mobile charge carriers that were flooding the diode in a conduction state have to be removed against the DC link voltage V_{DC}, which can be as high as several kV. If this charge is too large, then a high reverse current will flow through the diode against the high DC link voltage. This increases the diode losses, and the device will fail if the generated heat cannot be removed by a cooling system. On the other hand, if the amount of mobile charge is too small, then the reverse current will snap. The large gradient of the change of current per time that follows can induce dangerous overvoltages and additional electromagnetic noise in the system. Therefore, the diode should be designed with a compromise between low trade-off losses and snappiness. For very high voltages (e.g. 10 kV), the snappiness of the diode becomes even more critical. Such diodes need minimal losses and acceptable cosmic-ray rating, which, on the other hand, leads to a snappy behavior.

In DE 36 31 136 A1, the n-doping in front of the second (p+) doped zones 5 is higher, so that the resistivity becomes smaller. Therefore, to have a high injection efficiency, the second (p+) doped zones 5 have to be made larger. However, by doing that, the active area of the diode, i.e. the area in which first (n++) doped zones 4 are arranged, gets smaller and the leakage current also disadvantageously increases.

US 2006/0286753 A1 discloses a diode with an inner buffer layer with high doping, and an outer buffer layer arranged adjacent to the inner buffer layer with lower doping, but which is much higher than the doping of the base layer. In order to achieve a small current gradient, a large charge reservoir is needed. Such a large current reservoir is necessary because there is no additional injection available in this conventional diode. Such a large reservoir can only be achieved by a deep implant, for which high implantation energies are used. Such high energies, however, have negative influence on the structure of the device. Additionally, due to the high doping of the inner buffer layer, the blocking capability of the device is disadvantageously reduced.

### SUMMARY

An exemplary embodiment includes a base layer of a first conductivity type. The base layer has a first main side and a second main side opposite the first main side. The exemplary diode also includes an anode layer of a second conductivity type. The anode layer is arranged on the second main side. The exemplary diode also includes a plurality of first zones of the first conductivity type with a higher doping concentration than the base layer. In addition, the exemplary diode includes a plurality of second zones of the second conductivity type. The plurality of first and second zones are arranged alternately on the first main side. The exemplary diode also includes a cathode electrode and an anode electrode. The cathode electrode is arranged on top of the first and second zones on the side of the zones which lies opposite the base layer, and the anode electrode is arranged on top of the anode layer on the side of the anode layer which lies opposite the base layer. The base layer includes a first sublayer, which is formed by a part of the second main side of the base layer, and a second sublayer, which is formed by a part of the first main side of the base layer and which is in contact with the plurality of first and second zones. The exemplary diode also includes a third layer of the first conductivity type which is arranged between the first and second sublayer. The third layer has a higher doping concentration than the base layer and a lower doping concentration than the first zones.

A method for manufacturing a diode is disclosed, comprising: providing a wafer of a first conductivity type, the wafer having a first main side and a second main side opposite the first main side, part of the wafer forming a base layer in the diode;creating an anode layer of a second conductivity type on the second main side by implanting first ions into the second main side of the wafer; driving the implanted first ions into the wafer; creating a fourth layer by implanting second ions into the first main side of the wafer; driving the second ions into the wafer; applying a masking layer on the fourth layer; creating a plurality of first zones of the first conductivity type in the fourth layer through the masking layer, and forming a plurality of second zones of a second conductivity type in those parts of the fourth layer in which no first zones are created, such that the plurality of first and second zones are arranged alternately on the first main side, the plurality of first zones of the first conductivity type having a higher doping concentration than the base layer; a part of the base layer on the second main side forming a first sublayer, a part of the base layer on the first main side forming the second sublayer, the second sublayer being in contact with the plurality of first and second zones; irradiating the wafer with third ions to create a third layer of the first conductivity type between the first and second sublayers; annealing the third ions; and creating a cathode electrode on the first main side and an anode electrode on the second main side.

A method for manufacturing a diode is disclosed, comprising: providing a wafer of a first conductivity type, the wafer having a first side and a second side opposite the first side, part of the wafer forming a first sublayer in the diode; epitactically growing a third layer on the first side; growing a fifth layer on the third layer, part of the fifth layer forming a second sublayer in the diode; the first and second sublayer forming a base layer in the diode; creating a fourth layer by implanting second ions in the fifth layer; driving the second ions into the fifth layer; applying a masking layer on the fourth layer; creating a plurality of first zones of the first conductivity type in the fourth layer through the masking layer, and forming a plurality of second zones of a second conductivity type in those parts of the fourth layer in which no first zones are created, such that the plurality of first and second zones are arranged alternately, the plurality of first zones of the first conductivity type having a higher doping concentration than the base layer, and the plurality of first and second zones being in contact with the second sublayer; creating an anode layer of a second conductivity type on the second side by implanting first ions into the second side of the wafer;driving the implanted first ions into the wafer; irradiating the wafer with third ions to create a third layer of the first conductivity type between the first and second sublayers; annealing the third ions; and creating a cathode electrode on the first main side and an anode electrode on the second main side.

### BRIEF DESCRIPTION OF THE DRAWINGS

Additional refinements, advantages and features of the present disclosure are described in more detail below with reference to exemplary embodiments illustrated in the drawings, in which:

FIG. 1 shows a conventional rectifier diode with first (n++) zones and second (p+) doped zones;

FIG. 2 shows a conventional circuit of an IGCT switch and a free wheeling diode;

FIG. 3 shows the current waveforms during the turn-off process under snap off conditions of a conventional rectifier diode with second (p+) doped zones, where the rectifier fails to completely turn-off at low current;

FIG. 4 shows the voltage waveform during the turn-off process under snap off conditions of a conventional diode without second (p+) doped zones;

FIG. 5 shows the current waveform during the turn-off process under snap off conditions of a standard diode without second (p+) doped zones;

FIG. 6 compares the voltage waveforms during the turn-off process under snap off conditions of a conventional diode and an exemplary diode of the present disclosure, where both the conventional diode and the exemplary diode of the present disclosure have second (p+) doped zones;

FIG. 7 compares the current waveforms during the turn-off process under snap off conditions of a conventional diode and an exemplary diode of the present disclosure, where both the conventional diode and the exemplary diode of the present disclosure have second (p+) doped zones.

FIG. 8 shows an exemplary embodiment of a diode according to the present disclosure;

FIG. 9 shows a first manufacturing step for manufacturing an exemplary diode according to the present disclosure; and

FIGS. 10 to 21 show further manufacturing steps for manufacturing an exemplary diode according to the present disclosure.

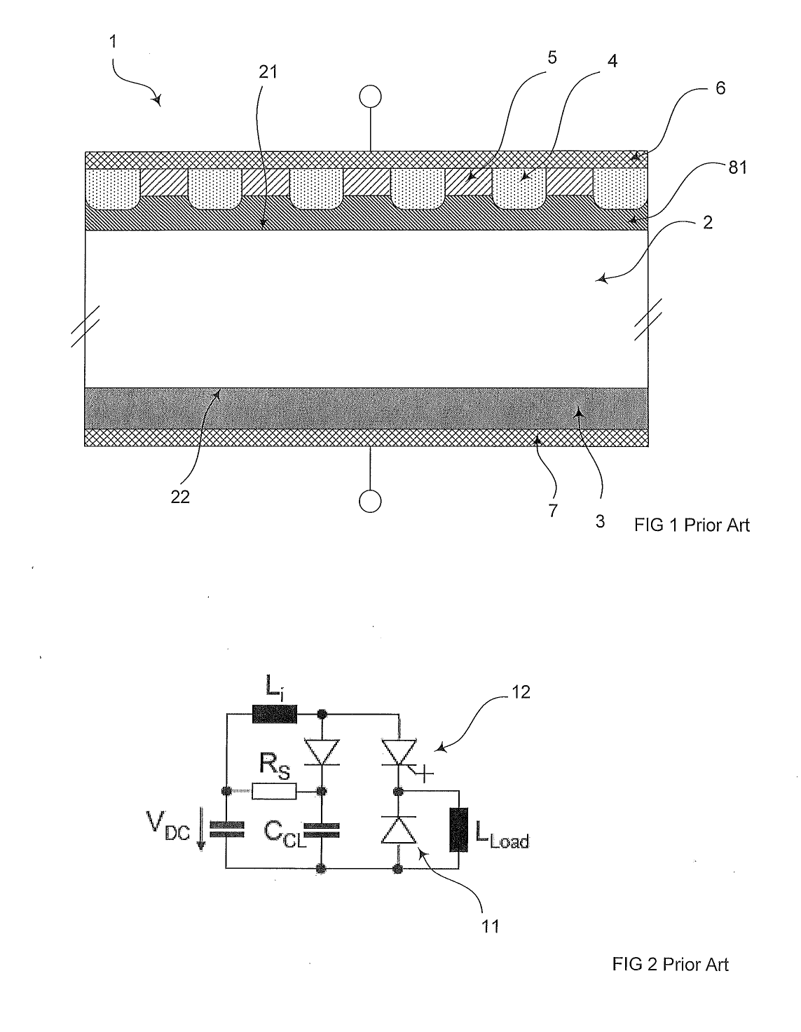

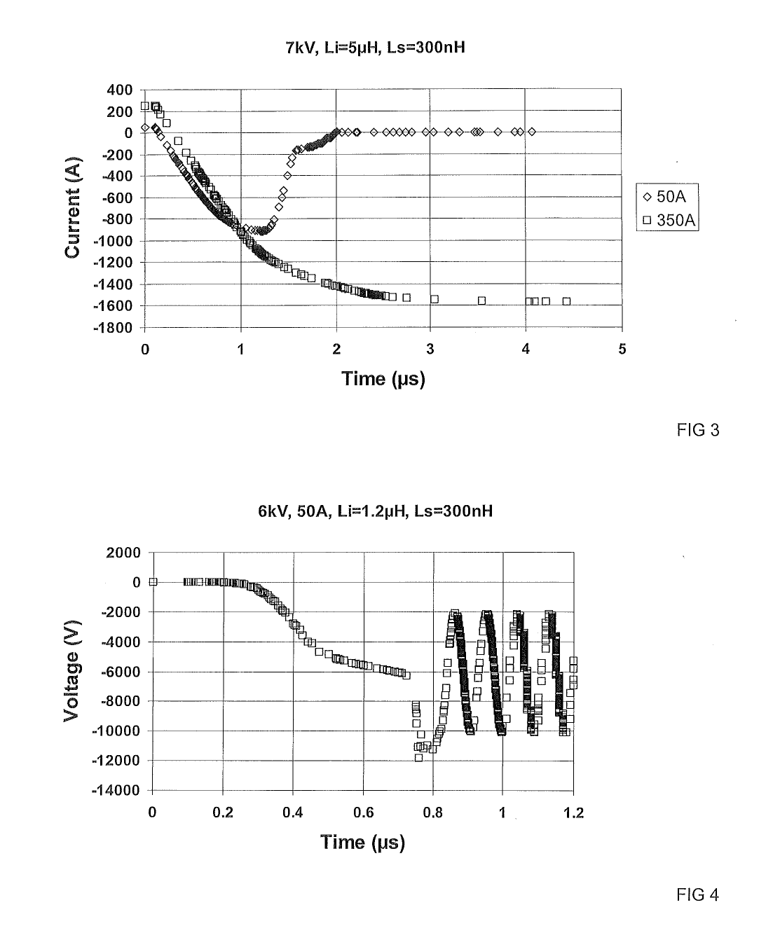

The reference symbols used in the drawings and their meaning are summarized in the list of reference symbols. Generally, alike or alike-functioning parts are given the same reference symbols. The described embodiments are meant as examples and shall not confine the disclosure.

### DETAILED DESCRIPTION

Exemplary embodiments of the present disclosure provide a diode for fast switching applications, which allows improved control over injecting charge carriers into the diode area and which has an enhanced effect of injection efficiency, while having a large active diode area. Exemplary embodiments of the present disclosure also provide a method for manufacturing such a diode.

An exemplary embodiment provides a diode which includes a first layer of a first conductivity type in form of a base layer having a first main side and a second main side opposite the first main side, a second layer of a second conductivity type, which is in form of an anode layer and which is arranged on the second main side, a plurality of first zones of the first conductivity type with a higher doping concentration than the base layer and a plurality of second zones of the second conductivity type. The first and second zones are arranged alternately on the first main side. The diode also includes first and second metal layers. The first metal layer is in the form of a cathode electrode arranged on top of the first and second zones on the side of the zones which lies opposite the base layer. The second metal layer is in the form of an anode electrode arranged on top of the anode layer on that side of the anode layer, which lies opposite the base layer. The base layer includes a first sublayer, which is formed by the second main sided part of the base layer, and a second sublayer, which is formed by the first main sided part of the base layer. Between the first and second sublayers, a third layer of the first conductivity type is arranged with a higher doping concentration than the base layer and a lower doping concentration than the first zones.

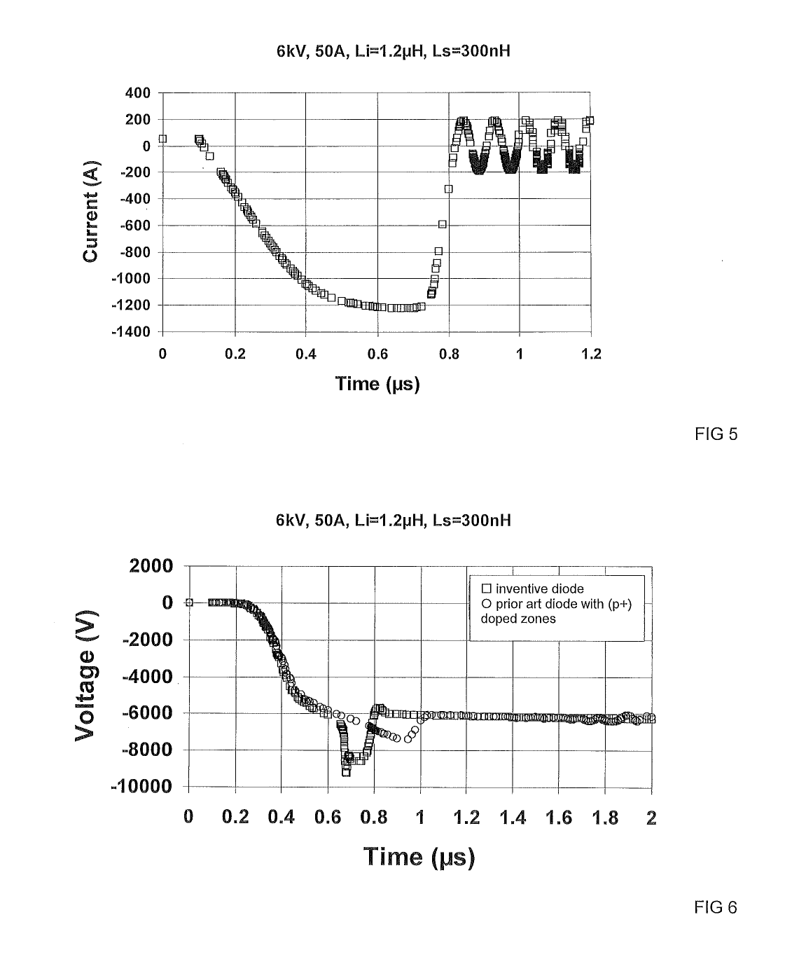

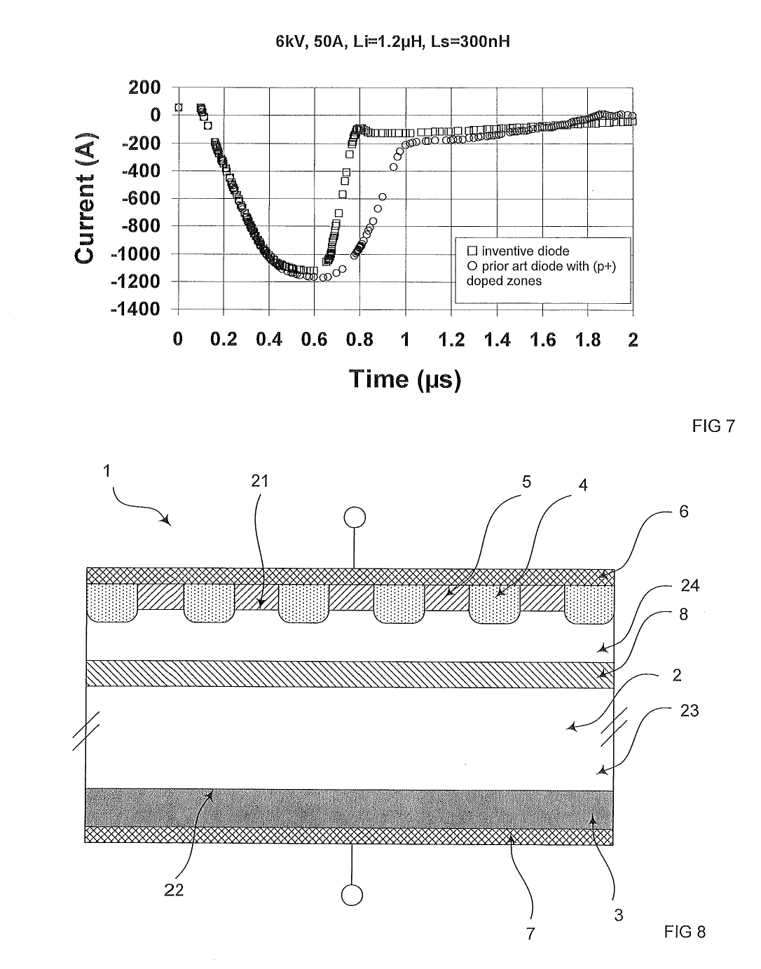

FIGS. 6 and 7 show for an exemplary diode at a voltage of 6 kV that the turn-off process becomes devoid of artefacts like over voltages or over currents. The current in the final stages of the turn-off process is decreasing slowly, being supported by the injection of holes from the second (p+) doped zones. The exemplary diode design presents a so-called self switching clamping mode, in which the voltage during the turn-off process remains at a constant voltage without the use of external electrical components. Yet another advantage of the exemplary diode design is a reduced turn-off energy. For the results presented herein, the reduction in turn-off energy is approximately 25%, from a value of 4.2 J for the standard buffer structure.

The exemplary diode is less susceptible to snap-off effects during switch-off of the diode and with lower trade-off losses than conventional devices.

As the exemplary diode has a charge reservoir from the third layer 8 and additionally charge carriers are injected from the second (p+) doped zones 5 the gradient of the current is improved. Consequently, the second (p+) doped zones 5 can be kept small and a shallow implant for the third layer is sufficient to achieve the desired charge reservoir from the third layer so that the inventive device has an improved high blocking voltage. The implant depth can be kept much lower than for instance for a prior art device as described in US 2006/0286753 A1 for a device of the same energy class. Furthermore, as the implantation energy for the shallow implant is relatively small (e.g. around 1 MeV) no undesired influences in the crystal constitution take place.

Besides, in the exemplary diode, there is a lower n doping in front of the second (p+) doped zones 5 as for instance compared to the device in DE 36 31 136 A1, so that the resistivity is advantageously increased.

The exemplary diode can be advantageously be used as a free-wheeling diode in IGCT (Integrated gate commutated thyristor) and/or IGBT (insulated gate bipolar transistor) applications.

As used herein, in the exemplary embodiments described below, a first conductivity type is an n-type conductivity, and a second conductivity type is a p-type conductivity. However, it is to be understood that the conductivities of the elements described below can be reversed.

FIG. 8 shows an inventive free-wheeling diode 1 including a first layer in the form of a base layer 2 of a first conductivity type, i.e. of n-type, with a first main side 21 and a second main side 22, which is opposite the first main side 21. A second p-doped layer in the form of an anode layer 3 is arranged on the second main side 22. A second metal layer in form of an anode electrode 7 is arranged on top of the anode layer 3, i.e. on that side of the anode layer 3 which lies opposite the base layer 2. On the first main side 21, a plurality of first (n++) doped zones 4 with a higher doping concentration than the base layer 2, and a plurality of second (p+) doped zones 5. The plurality of zones 4, 5 are arranged alternately, as illustrated in FIG. 8. A first metal layer in the form of a cathode electrode 6 is arranged on top of the first and second zones 4, 5, i.e. on that side of the zones which lies opposite the base layer 2. The base layer 2 includes two sublayers 23, 24. A first sublayer 23 is formed by the second main sided part of the base layer 2. The first sublayer 23 includes the second main side 22 and is arranged adjacent and in contact with the anode layer 3. A second sublayer 24 is formed by the first main sided part of the base layer 2. The second sublayer 24 includes the first main side 21 of the base layer 2 and is arranged adjacent and in contact with the first and second zones 4, 5. A third (n+) doped layer in the form of a deep buffer layer 8 is arranged between the first and second sublayer 24, 23. The third layer 8 has a higher doping concentration than the base layer 2 and a lower doping concentration than the first zones 4. The third layer 8, which is in form of a deep buffer layer, is arranged closer to the first main side 21 than to the second main side 22.

In accordance with an exemplary embodiment of the present disclosure, the area of all second (p+) doped zones 5 is more than 10% of the total area.

In accordance with another exemplary embodiment, the third layer 8 is arranged in a depth from the top of the first and second zones 4, 5, i.e. from the interface between the zones 4, 5 and the cathode electrode 6 of 20 to 50 μm. The doping concentration of the third layer 8 can be, for example, in the range of 10¹⁵ to 10¹⁷/cm².

In accordance with another exemplary embodiment, the second zones 5 have a diameter in a range between 50 μm and 400 μm. For example, the thickness of the second zones 5 is in a range between 2 μm and 20 μm, and/or the doping concentration is in a range between 10¹⁷ and 10¹⁹/cm².

In accordance with another exemplary embodiment, the diode 1 is used as a free-wheeling diode 11 for IGCT (Integrated gate commutated thyristor) or IGBT (insulated gate bipolar transistor) applications.

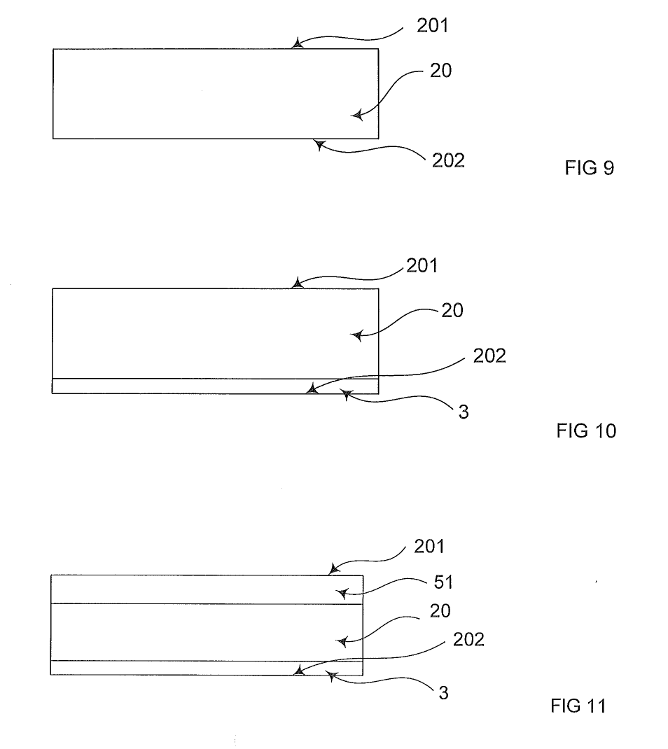

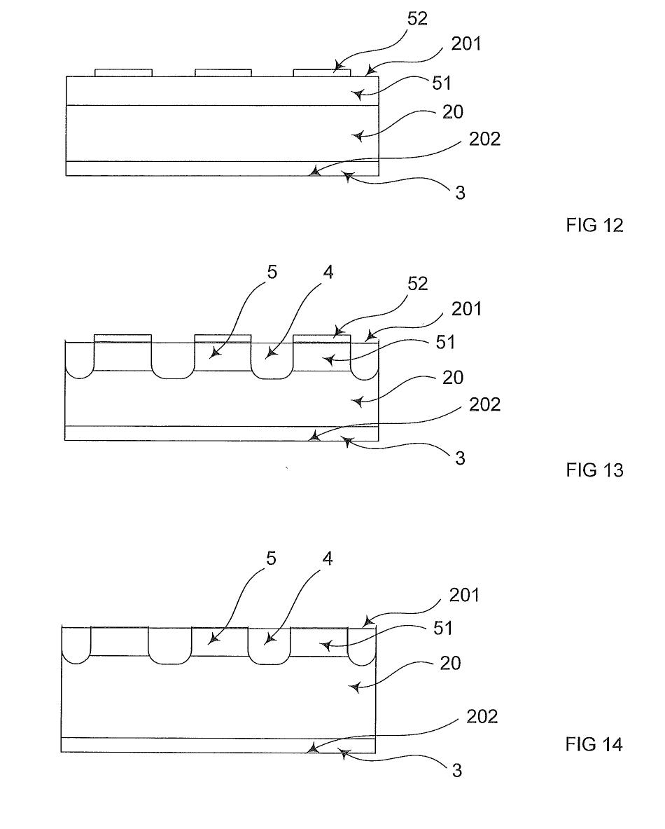

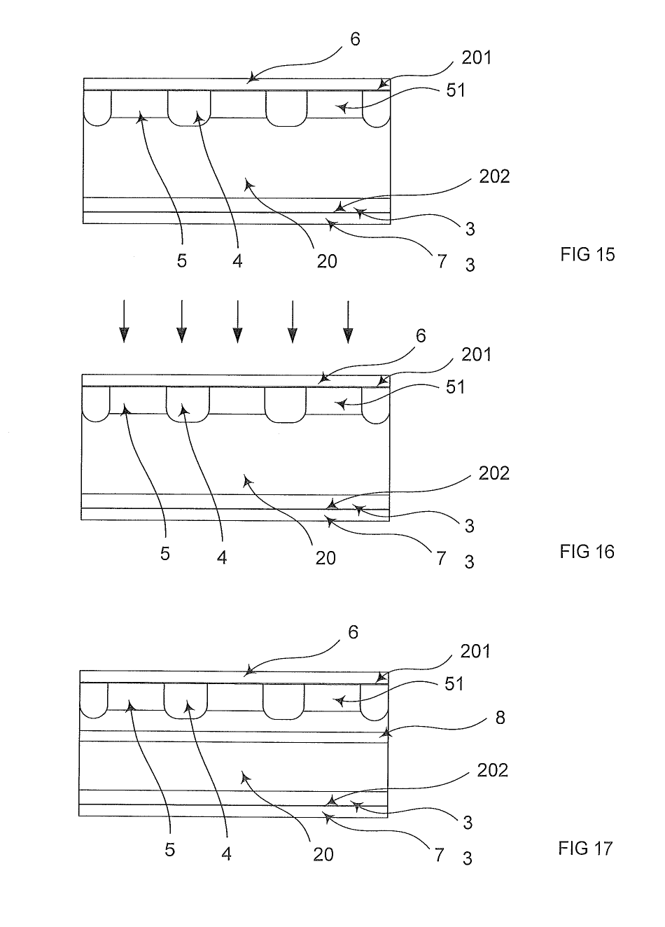

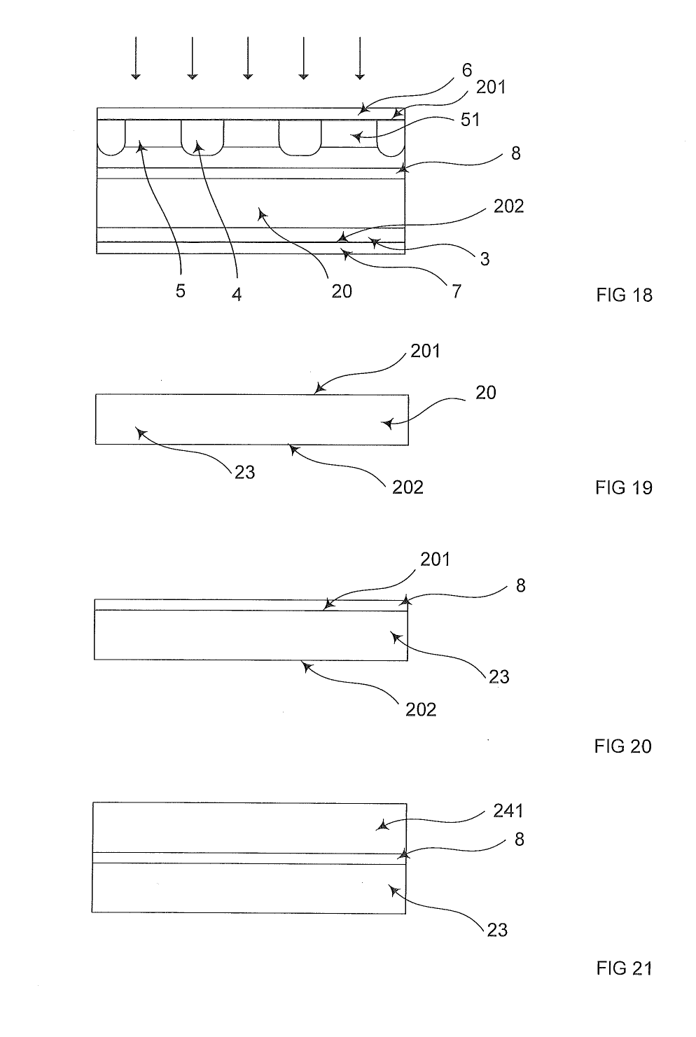

The diode can be manufactured by the following manufacturing method including the following steps. An n-type wafer 20 is provided with a first side 201 and a second side 202 opposite the first side 201 (FIG. 9). For the manufacturing of a p-n junction, on the second side 202 of the wafer 20, the second p-type anode layer 3 is created by a state of the art process of implantation of first ions followed by diffusion at high temperatures (FIG. 10). Afterwards, the first ions are driven into the wafer 20 up to the desired depth. For example, the first ions can be driven into the wafer 20 by heating the wafer 20 up to a temperature of 1000-1400° C. for several hours. A fourth n-type layer 51 is created by implanting second ions into the wafer 20 for the manufacturing of the second zones 5 (FIG. 11). According to an exemplary embodiment, boron and/or aluminium can used as the first ions, and phosphorus can be used as the second ion. Afterwards, the second ions are driven in the wafer by diffusion at a high temperature. Then, a masking layer 52 is created (FIG. 12). The creation of the masking layer 52 can be performed, for example, by applying a photoresist layer on the fourth layer 51 on the first side 201 and then creating the masking layer 52 in that layer. The first n-type zones 4 in the fourth layer 51 are created through the masking layer 52, for example, by a chemical process, and by drive-in process of the dopants at a lower temperature (FIG. 13). Those parts of the fourth layer 51 in which no first zones 4 are created, form the second zones 5. The masking layer 52 is removed (FIG. 14), and then a metallization process, for example, is performed on both sides of the wafer in order to create the first metal layer (cathode electrode) 6 as a cathode on the first side 201 and the second metal layer (anode electrode) 7 as an anode on the second side 202 (FIG. 15). An edge termination is made in order to improve the voltage blocking capability of the device. Afterwards, the wafer 20 is irradiated with third type ions (represented by the arrows in FIG. 16) for the manufacturing of the third layer 8 from the first side 201 and annealed (FIG. 17). According to an exemplary embodiment, the third type ions are protons. Energy and concentration of the ions are chosen such that the desired depth and dose concentration of the third layer 8 is achieved. Annealing temperatures are chosen such that the desired n-dopant concentration is obtained in the third layer 8. In a further step, the diode 1 may be irradiated with electrons over the whole device in order to further reduce turn-off losses of the device (represented by the arrows in FIG. 18).

Alternatively, the following manufacturing method can be used. An n-type wafer 20 is provided with a first side 201 and a second side 202 opposite the first side 201 (FIG. 19). The wafer 20 forms the first sublayer 24 of the base layer 2 in the finalized diode 1. A third n-type layer 8 with a higher doping than the wafer 20 is epitactically grown on the first side 201 of the wafer 20 (FIG. 20). The thickness of the third layer 9 can be 5 to 20 μm, for example. Afterwards, a fifth layer 241 is also epitactically grown on the third layer 8 on the side opposite the first sublayer 23 (FIG. 21), with a thickness of less than 100 μm, for example. That part of the fifth layer 241 which is not amended in doping by the creation of the first and second zones 4, 5 at a later manufacturing stage forms the first sublayer 24 in the finalized diode 1. After creation of the fifth layer 241, the first and second zones 4, 5 are created in the fifth layer 241 as described above. The anode layer 3, the first and second metal layers, as cathode and anode electrodes 6, 7, respectively, are also created as described above, and an electron irradiation may also be performed in the same manner.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE LIST

diode 1
base layer 2
wafer 20
first side 201
second side 202
first main side 21
second main side 22
second sublayer 23
first sublayer 24
fifth layer 241
anode layer 3
first zone 4
second zone 5
fourth layer 51
masking layer 52
cathode electrode 6
anode electrode 7
third layer 8
anode 9
cathode 10

1. A diode comprising:
a base layer of a first conductivity type, the base layer having a first main side and a second main side opposite the first main side;
an anode layer of a second conductivity type, the anode layer being arranged on the second main side;
a plurality of first zones of the first conductivity type with a higher doping concentration than the base layer;
a plurality of second zones of the second conductivity type, the plurality of first and second zones being arranged alternately on the first main side;
a cathode electrode and an anode electrode, the cathode electrode being arranged on top of the first and second zones on the side of the zones which lies opposite the base layer, and the anode electrode being arranged on top of the anode layer on the side of the anode layer which lies opposite the base layer,
wherein the base layer comprises a first sublayer, which is formed by a part of the second main side of the base layer, and a second sublayer, which is formed by a part of the first main side of the base layer and which is in contact with the plurality of first and second zones, and
wherein the diode further comprises a third layer of the first conductivity type which is arranged between the first and second sublayer, the third layer having a higher doping concentration than the base layer and a lower doping concentration than the first zones.

2. The diode according to claim 1, wherein the third layer is arranged in a depth from the top of the first and second zones of 20 to 50 μm.

3. The diode according to claim 1, wherein the second zones have at least one of a diameter in a range between 50 μm and 400 μm, a thickness in a range between 2 μm and 20 μm, and a doping concentration in a range between 10¹⁷ and 10¹⁹/cm².

4. The diode according to claim 1, wherein the first zones have at least one of a diameter in a range between 50 μm and 400 μm, a thickness in a range between 2 μm and 20 μm, and a doping concentration in a range between 10¹⁷ and 10¹⁹/cm².

5. An integrated gate commutated thyristor comprising a diode as a free-wheeling diode according to claim 1.

6. A method for manufacturing a diode, comprising:
providing a wafer of a first conductivity type, the wafer having a first main side and a second main side opposite the first main side, part of the wafer forming a base layer in the diode;
creating an anode layer of a second conductivity type on the second main side by implanting first ions into the second main side of the wafer;
driving the implanted first ions into the wafer;
creating a fourth layer by implanting second ions into the first main side of the wafer;
driving the second ions into the wafer;
applying a masking layer on the fourth layer;
creating a plurality of first zones of the first conductivity type in the fourth layer through the masking layer, and forming a plurality of second zones of a second conductivity type in those parts of the fourth layer in which no first zones are created, such that the plurality of first and second zones are arranged alternately on the first main side, the plurality of first zones of the first conductivity type having a higher doping concentration than the base layer;
a part of the base layer on the second main side forming a first sublayer;
a part of the base layer on the first main side forming the second sublayer, the second sublayer being in contact with the plurality of first and second zones;
irradiating the wafer with third ions to create a third layer of the first conductivity type between the first and second sublayers;
annealing the third ions; and
creating a cathode electrode on the first main side and an anode electrode on the second main side.

7. The method for manufacturing a diode according to claim 6, wherein the first type ions are at least one of boron and aluminum.

8. A method for manufacturing a diode, comprising:
providing a wafer of a first conductivity type, the wafer having a first side and a second side opposite the first side, part of the wafer forming a first sublayer in the diode;
epitactically growing a third layer on the first side;
growing a fifth layer on the third layer, part of the fifth layer forming a second sublayer in the diode; the first and second sublayer forming a base layer in the diode;
creating a fourth layer by implanting second ions in the fifth layer;
driving the second ions into the fifth layer;
applying a masking layer on the fourth layer;
creating a plurality of first zones of the first conductivity type in the fourth layer through the masking layer, and forming a plurality of second zones of a second conductivity type in those parts of the fourth layer in which no first zones are created, such that the plurality of first and second zones are arranged alternately, the plurality of first zones of the first conductivity type having a higher doping concentration than the base layer, and the plurality of first and second zones being in contact with the second sublayer;
creating an anode layer of a second conductivity type on the second side by implanting first ions into the second side of the wafer;
driving the implanted first ions into the wafer;
irradiating the wafer with third ions to create a third layer of the first conductivity type between the first and second sublayers;
annealing the third ions; and
creating a cathode electrode on the first main side and an anode electrode on the second main side.

9. The method for manufacturing a diode according to claim 6, comprising:
irradiating the whole diode with electrons after the creation of all layers.

10. The diode according to claim 1, wherein the third layer has a doping concentration in a range of 10¹⁵ to 10¹⁷/cm².

11. The diode according to claim 2, wherein the third layer has a doping concentration in a range of 10¹⁵ to 10¹⁷/cm².

12. The diode according to claim 2, wherein the second zones have at least one of a diameter in a range between 50 μm and 400 μm, a thickness in a range between 2 μm and 20 μm, and a doping concentration in a range between 10¹⁷ and 10¹⁹/cm².

13. The diode according to claim 2, wherein the first zones have at least one of a diameter in a range between 50 μm and 400 μm, a thickness in a range between 2 μm and 20 μm, and a doping concentration in a range between 10¹⁷ and 10¹⁹/cm².

14. The diode according to claim 3, wherein the first zones have at lease one of a diameter in a range between 50 μm and 400 μm, a thickness in a range between 2 μm and 20 μm, and a doping concentration in a range between 10¹⁷ and 10¹⁹/cm².

15. An insulted gate bipolar transistor comprising a diode as a free-wheeling diode according to claim 1.

16. The method for manufacturing a diode according to claim 6, wherein the second type ions are phosphorus.

17. The method for manufacturing a diode according to claim 6, wherein the third type ions are protons.

18. The method for manufacturing a diode according to claim 7, comprising:
irradiating the whole diode with electrons after the creation of all layers.

19. The method for manufacturing a diode according to claim 8, comprising:
irradiating the whole diode with electrons after the creation of all layers.
